(19) United States
(12) Patent Application Publication
(10) Pub. No.: US 2023/0407475 A1
(43) Pub. Date: Dec. 21, 2023

(54) Fully open-air combustion deposition and rapid plasma treatment of metal oxides

(71) Applicant: The Board of Trustees of the Leland Stanford Junior University, Stanford, CA (US)

(72) Inventors: Reinhold H. Dauskardt, Menlo Park, CA (US); Thomas W. Colburn, Redwood City, CA (US); Robert D. Miller, San Jose, CA (US); Nicholas Rolston, Phoenix, AZ (US)

(21) Appl. No.: 18/200,280

(22) Filed: May 22, 2023

Related U.S. Application Data
(60) Provisional application No. 63/344,403, filed on May 20, 2022.

(51) Int. Cl. C23C 16/455; C23C 16/06; C23C 16/56

(52) U.S. Cl. CPC C23C 16/45553; C23C 16/06; C23C 16/56

(57) ABSTRACT

Fabrication of thin-film metal oxide layers is performed by combining deposition of an oxidant-containing precursor, combustion of the precursor to form a thin-film metal oxide layer, and plasma treating the thin-film metal oxide layer. In one example, rapid fabrication of high-quality indium tin oxide thin films is demonstrated.

### CROSS REFERENCE TO RELATED APPLICATIONS

This application claims the benefit of U.S. provisional patent application 63/344,403, filed on May 20, 2022, and hereby incorporated by reference in its entirety.

### GOVERNMENT SPONSORSHIP

This invention was made with Government support under contract DE-EE0009516 awarded by The Department of Energy. The Government has certain rights in the invention.

### FIELD OF THE INVENTION

This invention relates to fabrication of thin-film metal oxides.

### BACKGROUND

Metal oxides are vitally important as ceramics, magnetic materials, electronic insulators, semiconductors, and conductors in various applications. Generally, the preparation of metal oxides requires high temperature and/or high vacuum deposition methods which, in turn, limit the processing techniques capable of forming the materials and demand energy intensive processing to yield desirable characteristics. One valuable class of metal oxides include transparent conducting oxides (TCOs) with tin-doped indium oxide (ITO) being among the most important. Despite the importance of TCOs for various industries including consumer electronics, solar cells, OLEDs, and electronic glass, the fabrication of high-quality TCOs generally involves time-intensive, expensive, and low-throughput manufacturing techniques (sputtering, chemical vapor deposition, or atomic layer deposition) that are a bottleneck for accelerated in-line or roll-to-roll processing. Cost modeling of a 100 MW production line implicates ITO as one of the most expensive device layers for perovskite solar cell production before encapsulation due to the traditionally implemented vacuum-based deposition techniques.

While open-air, scalable ITO synthesis techniques have been widely studied including spray pyrolysis and sol-gel, these methods have thus far tended to have disadvantages such as long annealing times, poor electrical conductivity, and/or release of environmentally harmful reaction products. Accordingly, it would be an advance in the art to provide improved fabrication of metal oxides.

### SUMMARY

In this work, fabrication of thin-film metal oxide layers is performed by combining deposition of an oxidant-containing precursor, combustion of the precursor to form a thin-film metal oxide layer, and plasma treating the thin-film metal oxide layer.

In one example, we demonstrate fabrication of indium tin oxide through a combined ultrasonic spray process with open-air environmentally-tunable plasma to shorten the time and costs associated with sputtered-quality TCO fabrication. In this example, a nitrate salt and organic complexing agent are ultrasonic spray deposited in open-air, heated until combustion and thin-film formation occurs, and then rapidly cured via an environmentally-tailored, open-air plasma to generate a metal oxide product with desired optical, electronic, morphological, and crystalline properties. This method is intrinsically scalable to larger area metal oxide films without the need for vacuum-based processing procedures. The resulting ITO films are conductive (<60 ohm/sq) and highly transparent (>85% Transmittance over the visible range) films fabricated in under 20 minutes of active processing time. For this example we used a chloride-free combustion synthesis allowing for a highly tunable, more “green” chemistry for the fabrication of a range of metal oxide materials including ITO and other TCO materials without producing corrosive chloride by-products.

Open-air spray processed ITO and other conducting metal oxides can be utilized in a wide array of applications including for OLEDs, photovoltaics, plasma displays, electrochromic windows, and consumer electronics. Outside of the electronics space, transparent conducting oxides are generally infrared mirrors and can be used as window treatments for improved heating and cooling efficiencies in buildings. An especially important application for this work is in the area of thin-film solar cells and modules to integrate these rapid, open-air fabricated electrodes into perovskite solar cells. ITO thin-film conductors are also often employed in organic solar cells and for flexible electronics. Additional non-conducting metal oxide materials could be used in situations such as but not limited to high-k dielectrics or semiconducting device layers (e.g. ZrO₂, etc.) in microelectronics.

Advantages over sputtering and other vacuum based techniques: Our process utilizes fully open-air processes meaning that a vacuum or inert environment is never required to fabricate the films. Removing the need for vacuum substantially mitigates the required time (removing the ˜1 hour vacuum pulling step) and equipment costs needed to fabricate TCO thin films. Further, our process makes the metal oxide in situ rather than requiring the high purity metal oxides be formed into processed pellets and then sputtered onto the substrate. This reduces the number of required steps in fabrication and gives an open-air, rapid technique for forming metal oxide conducting thin-films.

Advantages over sol-gel: Sol-gel TCO/metal oxide fabrication can produce porous metal oxide matrices resulting in lower density films with excessive roughness due to the formation of solvated metal oxide colloidal particles in the sol. Mitigation of porosity requires high temperature sintering, often under pressure, which can be lengthy and labor-intensive. Additionally, the metal alkoxide precursors and solutions can be both expensive and unstable over long periods of time and various humidity conditions. Our metal nitrate and oxidizable complexing agent-based solutions have shown to be highly stable for weeks to months with no precipitate formation or aggregation.

Advantages over spray pyrolysis: Spray pyrolysis uses the metal chloride species rather than metal nitrate to conduct the reaction and often requires temperatures exceeding 500° C. In this ITO example, using the exothermic combustion of the intrinsic reactants of the solution (e.g. the acetylacetone complexes) allows for the reduction of the required applied temperatures and eliminates the presence of corrosive chloride-based by-products derived from the metal chloride precursor salts.

### BRIEF DESCRIPTION OF THE DRAWINGS

FIG. 1 shows an exemplary embodiment of the invention.

FIG. 2 shows an example of plasma treatment used to introduce oxygen vacancies.

FIG. 3 shows thermogravimetric characterization results for an ITO film fabricated as described herein.

FIG. 4A-C show various characterization results for ITO films fabricated as described herein.

FIGS. 5A-C show atomic force microscope characterization results for ITO films fabricated as described herein, compared to a sputtered ITO control sample.

FIGS. 6A-B shows mass spectrometry of two different plasmas.

FIG. 6C shows optical spectroscopy of the two plasmas of FIGS. 6A-B

### DETAILED DESCRIPTION

### A) General Principles

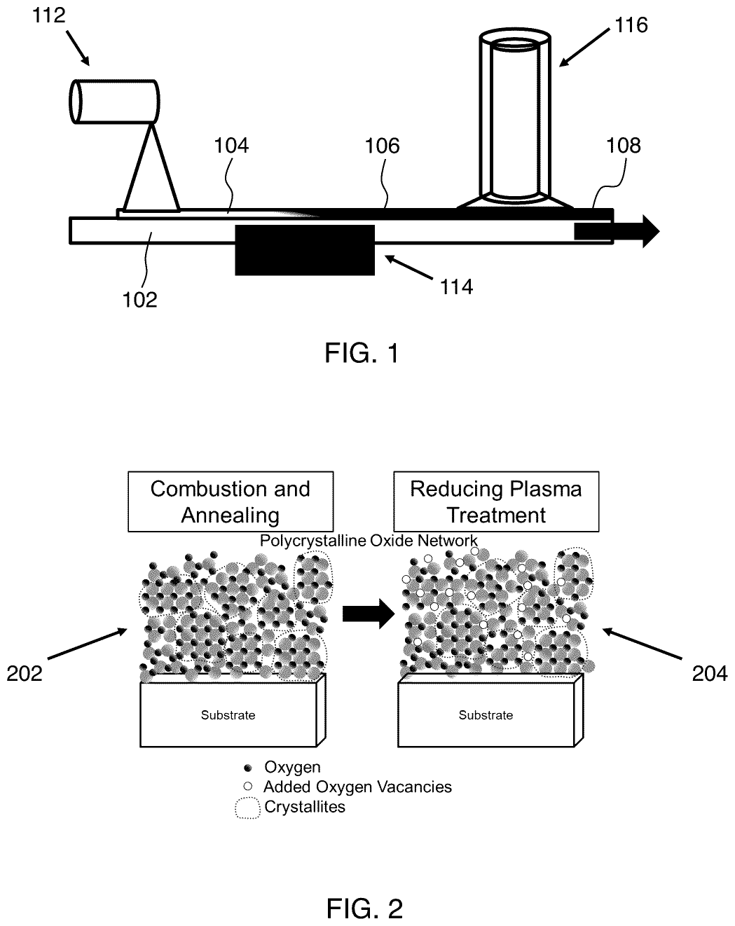

FIG. 1 schematically shows an embodiment of the invention. This example is a method of making a thin-film metal oxide layer. A precursor 104 is deposited on substrate 102 via deposition 112. Precursor 102 is combusted in step 114 to form a thin-film metal oxide layer 106. After that, thin-film metal oxide layer 106 is plasma treated with a plasma discharge 116 to provide a plasma-treated thin-film metal oxide layer 108. The precursor includes an oxidant, which can be done in three ways: by including a metallic oxidant salt species, by including a combination of a metallic non-oxidant salt species with a non-metallic oxidant species, or including a metallic non-oxidant salt species with an oxidant-containing complexing agent. The precursor also includes an organic complexing fuel species. Oxygen for the thin-film oxide layer comes at least in part from oxidant in the precursor. Aspects of this general method will be considered in turn in the following description.

Combustion is defined herein as rapid exothermic reaction involving oxidation which generates heat/light at a rate in which the heat is unable to be dissipated away from the sample, thereby resulting in a temperature increase of the sample.

### A1) Deposition

Practice of the invention does not depend critically on the substrate. Suitable substrates include, but are not limited to: quartz, glass, UV and/or ozone treated glass, metals, metal oxides, polymers and polar surfaces.

Practice of the invention also does not depend critically on how the precursor is deposited. Suitable deposition methods include, but are not limited to: ultrasonic spray deposition, blade coating, slot-die coating, spin coating, meniscus deposition, ink jet printing and gravure printing. Preferably, deposition is performed by moving a nozzle or the like over the substrate at a speed of 1 mm/s or more, and more preferably at a speed of 1 cm/s or more.

As an example, the solution for ultrasonic deposition can be injected via syringe pump through an ultrasonic oscillating nozzle tip. The resulting droplets formed are deposited on the film as the nozzle moves across the substrate at speeds of approximately ≥1 mm/s (more preferably 1 cm/s or more).

### A2) Precursors

The precursor is required to include metallic species corresponding to the metal oxide to be grown (both for composition and doping), oxidants, and fuel. Subject to these conditions, practice of the invention does not depend critically on specific reagents or the like. In the following, several examples for each precursor constituent are given

Suitable metallic elements for inclusion in the metallic oxidant salt species include, but are not limited to: Li, Na, Mg, Al, K, Ti, Co, Ni, Cu, Zn, Ga, Zr, Cd, In, Sn, Ba, La, Hf and Ta.

Suitable oxidants for inclusion in the metallic oxidant salt species include, but are not limited to: nitrates, chlorites, chlorates, perchlorates, hypochlorites, peroxydisulfates, peroxymonosulfates.

Suitable metallic elements for inclusion in the metallic non-oxidant salt species include, but are not limited to: Li, Mg, Al, Ti, Co, Ni, Cu, Zn, Ga, Zr, Cd, In, Sn, Ba, La, Hf and Ta.

The metal ions can principally be derived from metal nitrates along with metal acetylacetonate salts. Additionally, polar soluble materials such as metal chlorides, acetates, oxynitrates, fluorides, sulfates and organo-ligated complexes (i.e. oxalate, malonate, propoxide) can be utilized. When a non-nitrate metal ion source is used, subsequent nitrate oxidant sources can be introduced to the solution such as ammonium nitrate, organic amine nitrate salts, or quaternary ammonium nitrates (e.g. tetramethyl ammonium nitrate, etc.).

Suitable compounds for inclusion in the metallic non-oxidant salt species include, but are not limited to: metal acetylacetonate salts, metal chlorides, metal acetates, metal oxynitrates, metal fluorides, metal sulfates, metallic organo-ligated complexes, metal oxalates, and metal alkoxides.

Suitable compounds for inclusion in the non-metallic oxidant salt species include, but are not limited to: ammonium nitrate, organic amine nitrate salts, quaternary ammonium nitrates, tetramethyl ammonium nitrate, chlorites, chlorates, perchlorates, hypochlorites, peroxydisulfates, and peroxymonosulfates.

Suitable non-salt species for inclusion in the non-metallic oxidant species include, but are not limited to: nitric acid, peroxydisulfuric acids, peroxymonosulfuric acids, peracids, aliphatic or aromatic organic nitro compounds, nitrobenzene, nitropropane, nitroethane, nitrous oxides, peroxide-containing organic species, peroxides, and hydroperoxides.

The organic complexing fuel species preferably acts as a metal complexing ligand to reduce metal hydroxide and/or oxide premature condensation and to promote solubility of metallic species in organic solvents.

Suitable complexing compounds for inclusion in the at least one organic complexing fuel species include, but are not limited to: alcohols, ketones, aldehydes, carboxylic acids, esters, ethers, oximes, hydroxamic acids, diols, polyols, polyfunctional ethers, dimethoxyethane, polyethylene glycols, alpha and beta hydroxy aldehydes, beta diketones, beta keto esters, beta keto acids, and oxylates.

Suitable oxidizing species for inclusion in the at least one organic complexing fuel species include, but are not limited to: aromatic organic nitro compounds, aliphatic organic nitro compounds, nitroacetylacetone, nitro carboxylic acids, organic peroxides, organic hydroperoxides, and organic peracids. Oxygen for the thin-film metal oxide can comes in part from oxidizing species that are part of the organic complexing fuel species.

Ideally, the organic complexing fuel species should serve both as a metal complexing ligand to prevent volatilization and promote solubility in organic solvents and as a fuel for the oxidative combustion, where localized exothermicity drives the formation of the metal oxide films. Combustible ligands usually contain carbon and hydrogen, but may contain other elements as well which support or enhance the combustion process. Due to the generally strong nature of the bonding between polyvalent metal ions and oxygen functionalities, we have focused initially on these materials. To improve complexation, the ligands are often polydentate and the functionality can be mixed and matched (e.g. methoxyethanol etc.). To serve as a fuel, these materials should be combustible in the presence of an oxidizing agent such as nitrate ions, organic nitrates, nitrites, nitro derivatives. These examples are meant to be representative rather than comprehensive. Furthermore, solvent/fuel combinations such as oxidizing/oxidizable species like nitrobenzene, nitropropane, and nitroethane can be considered as possible oxidizing/fuel sources that also solubilize the metal salts.

### A3) Plasma Treatment

The open-air plasma treatment can provide various functions, including but not limited to: introducing oxygen vacancies, removing oxygen vacancies, exposure to ultraviolet light, elimination of dangling bonds, surface passivation, altering surface wetting properties, introducing surface defects, introducing bulk defects, densifying the thin-film metal oxide layer, performing precursor photolysis, and inducing crystallization.

Oxidation to form the thin-film oxide can be completed prior to the plasma treating. Alternatively, oxidation to form the thin-film oxide can be completed during the plasma treating. In other words, practice of the invention does not depend critically on whether all oxidation to form the thin film metal oxide layer occurs in the combustion step, or if some is done in the combustion step and the rest is done in the plasma treatment step.

The open-air plasma can provide various chemical environments including, but not limited to: reducing environments, oxidizing environments, and inert environments. Suitable plasma discharges for the open-air plasma include, but are not limited to: blown arc discharges, capacitor discharges, microwave discharge, RF (radio frequency) discharges, and flame plasmas. Practice of invention does not depend critically on the technique used to provide the open-air plasma.

Suitable ionization gases for the open-air plasma include, but are not limited to: air, oxygen, hydrogen in nitrogen, hydrogen in argon, hydrogen in helium, hydrogen in xenon, hydrogen in krypton, helium, argon, nitrogen, krypton, and xenon.

The open-air plasma can include a gas shroud surrounding an afterglow of the open-air plasma. Suitable gases for the gas shroud include, but are not limited to: air, oxygen, hydrogen in nitrogen, hydrogen in argon, hydrogen in helium, hydrogen in xenon, hydrogen in krypton, helium, argon, nitrogen, krypton, and xenon.

In the case of arc discharge, a high power discharge>5 kV occurs with a grounded electrode. Ionization gas introduced at flow rates from 5 LPM to 100 LPM (liters per minute) flows across this discharge and generates reactive radical and ionic species and high energy UV photons. The duty cycle of the plasma can be regulated between <15-100% corresponding to the incidence of activity (on vs off) time of the plasma over its discharge frequency. The formed plasma species (ions and radicals) then flow through a nozzle and out of the orifice into open-air to form the afterglow. Surrounding the afterglow, a shroud gas can be injected comprising a reductive, oxidative, and/or chemically neutral composition as described above for the ionization gas. This shroud gas is not ionized directly by the arc, capacitance discharge, or flame directly but becomes ionized by interactions directly with the nozzle afterglow and UV light emission of the system. The plasma temperature, ranging from room temperature to >500° C. can be adjusted by the height of the plasma relative to the surface (generally from 0-3 cm), the flow rate of gas across the arc, processing speed/dwell time of the plasma across the surface of interest, and the presence of the stainless steel shroud material. The optical emission of the plasma and ionic/radical composition will depend on the plasma parameters, the ionization gas, shroud gas, and ambient processing conditions.

In general, the rapid in-line gas plasma treatment helps to rapidly generate high quality conducting thin-films. The plasma anneal can introduce a reducing, oxidizing, or neutral (inert) atmospheric plasma over our sample surface driven by the formation of reactive ionic/radical species, heat, and high energy UV light that work in tandem to remove solvent, cure precursors, and densify the thin-film. In the case of TCOs, forming gas plasma can be leveraged to introduce oxygen vacancies and free electrons in the film resulting in improved conductivity. In high temperature ceramics, an oxygen shroud gas could be used to convert the precursors to the oxide at lower temperatures.

### B) Experimental Demonstration

In the work of the following examples, the above-described approach is used for the rapid fabrication of high quality ITO thin films. More specifically, a versatile ITO precursor chemistry comprising metallic nitrate hydrate salts (as described above) are dissolved with oxidizable complexing agents (such as beta diketones, beta keto esters, and beta keto acids, polycarboxylic acids) in a polar solvent and deposited via ultrasonic spray coating while mitigating the need for the traditionally-used tin IV chloride hydrate (all as described above).

An overview of the fabrication of the samples of this example follows. After deposition of the ITO precursors (indium nitrate, tin acetylacetonate, acetylacetone, and ammonium hydroxide in 2-methoxyethanol solvent), the resulting films are immediately heated to >250° C., combusted in under 1 minute via rapid thermal annealing, arc discharge plasma afterglow, or hotplate, and then annealed for <15 min in the afterglow of an open-air plasma injected with forming gas to introduce oxygen vacancies while simultaneously improving or maintaining existing film crystallinity. This scalable method has among the highest reported throughput for TCO films deposited at low temperatures (≤400° C.) and achieves sheet resistances of approximately <60 ohm/sq with transmittances>85% in the visible region. The process removes the need for long anneals and allows for film fabrication in under 20 minutes of direct processing time.

FIG. 2 is a molecular schematic of the plasma-initiated defect engineering process where treatment with a forming gas plasma results in more oxygen vacancies in the plasma-treated thin film 204 than in the thin film 202 present after the combustion step.

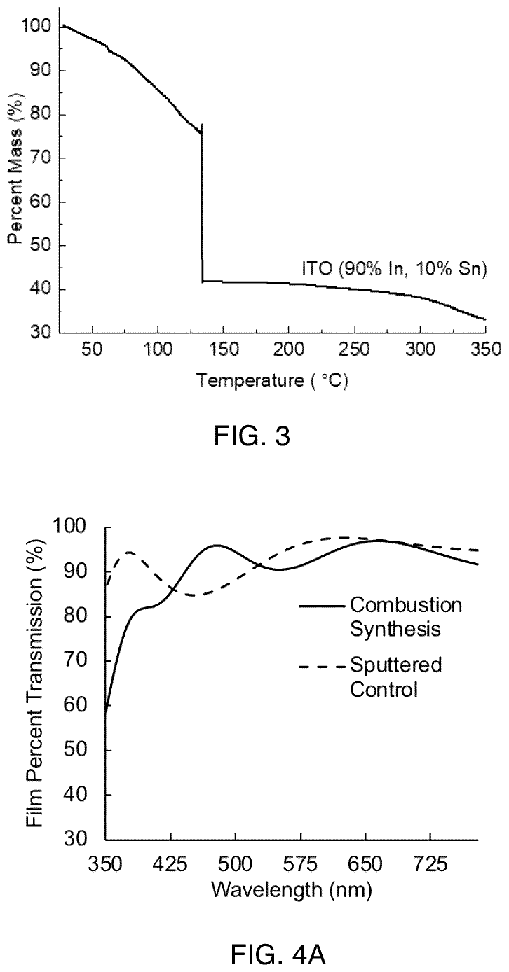

FIG. 3 shows solution combustion properties of indium tin oxide in a thermogravimetric analyzer. Here we see a low combustion temperature of roughly 130° C. for the oxidation of the precursor powder.

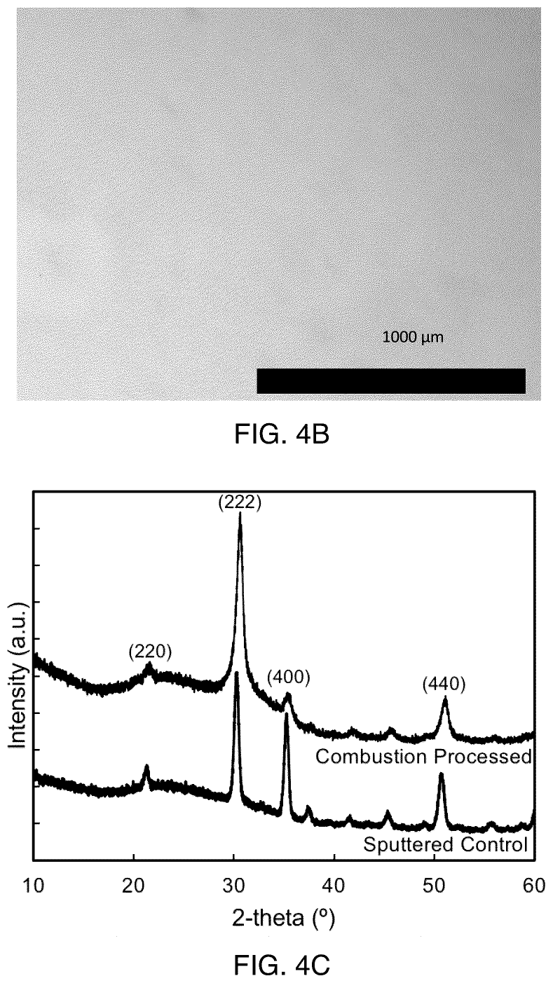

FIG. 4A shows substrate-subtracted UV/Vis spectroscopy results for an ITO film fabricated as described above, showing high optical transmittance (i.e., transmittance comparable to the sputtered ITO control sample). FIG. 4B is an optical microscopy image of an ITO film fabricated as described above, showing a lack of observable defects in this imaging modality. FIG. 4C shows grazing-incidence X-ray diffraction results for an ITO film fabricated as described above, showing similar crystallinity especially with (222) texture as the sputtered ITO control sample.

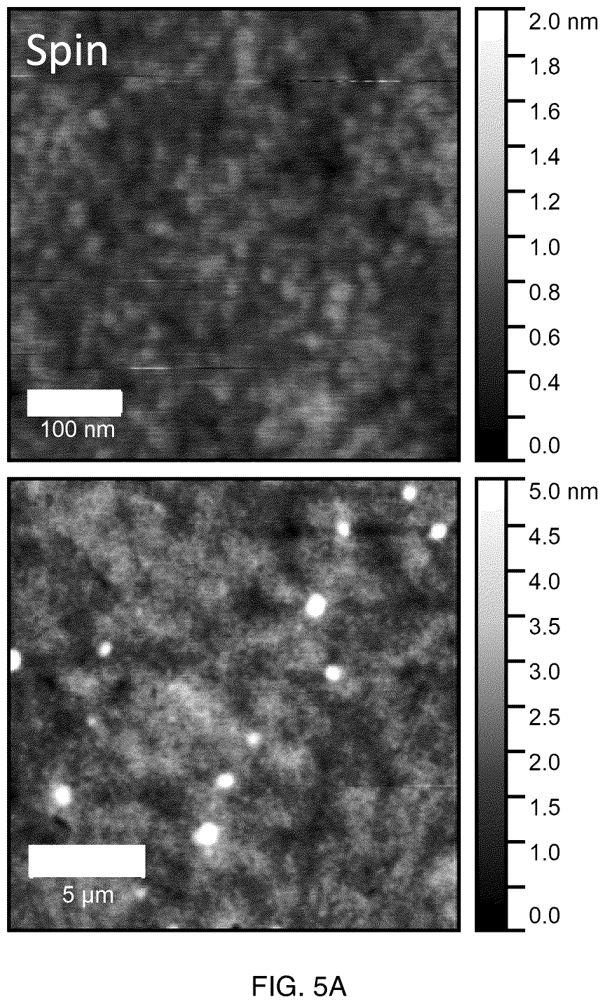

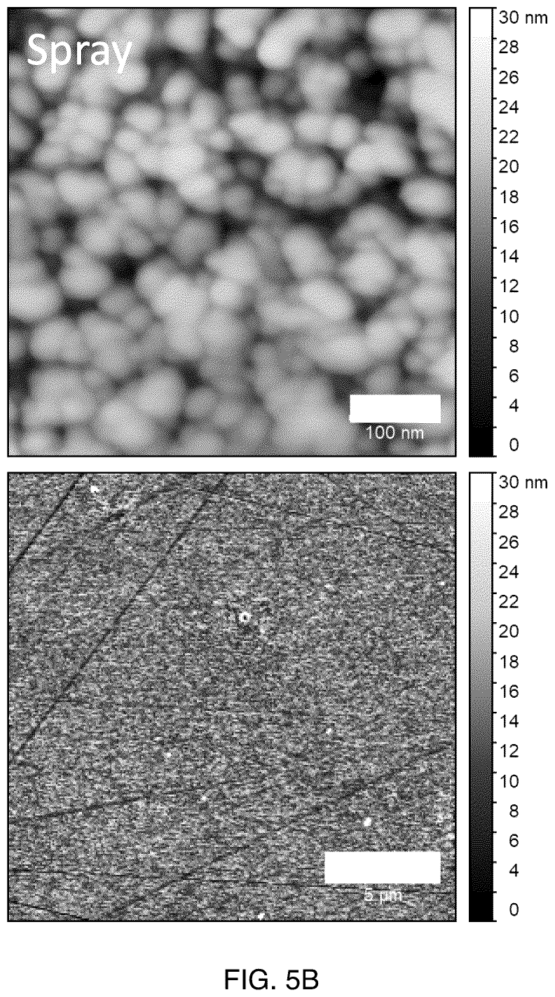

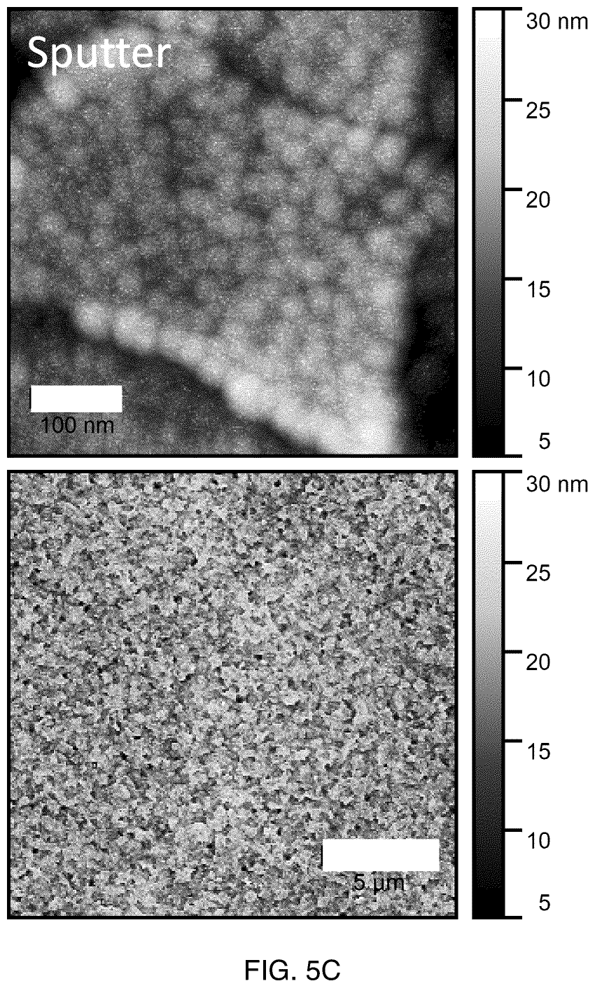

FIG. 5A shows atomic force microscopy images of a spin-coated ITO film fabricated as described above. The surface uniformity here is comparable to that of the sputtered control sample. FIG. 5B shows atomic force microscopy images of a spray-coated ITO film fabricated as described above. The surface morphology here is also comparable to that of the sputtered control sample. FIG. 5C shows atomic force microscopy images of a control ITO film fabricated by conventional sputtering. For each of FIGS. 5A-5C, the scale bar in the top image is 100 nm and the scale bar on the bottom image is 5 um.

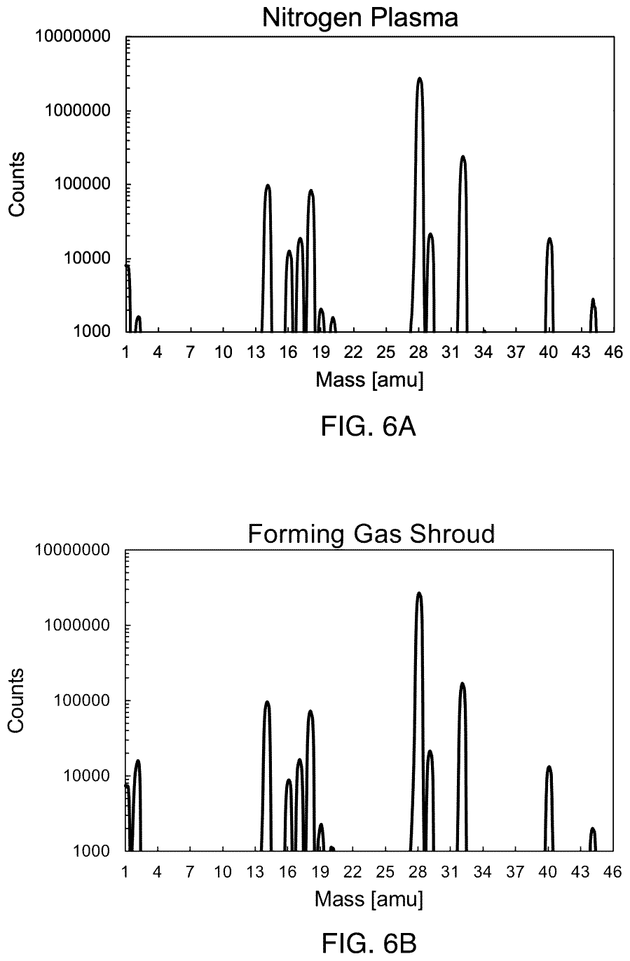

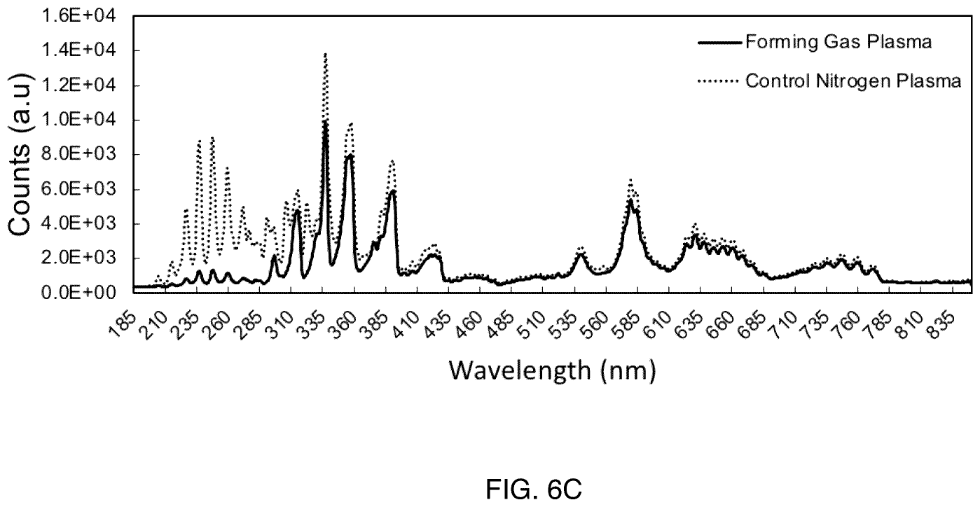

FIGS. 6A-6B shows mass spectrometry results of a nitrogen plasma (FIG. 6A) and of a nitrogen plasma with a forming gas shroud (FIG. 6B). FIG. 6B shows a higher concentration of Z=2 species indicating the presence of molecular hydrogen in the gases of the blend. Hydrogen-containing species are able to promote the generation of oxygen vacancies. FIG. 6C shows corresponding optical spectroscopy results, showing a clear difference in composition between the two plasma environments.

1. A method of making a thin-film metal oxide layer, the method comprising:
depositing a precursor on a substrate, wherein the precursor includes
i) at least one metallic oxidant salt species or a combination of a metallic non-oxidant salt species with a non-metallic oxidant species, and
ii) at least one organic complexing fuel species;
combusting the precursor to form a thin-film metal oxide layer, wherein oxygen for the thin-film metal oxide layer comes at least in part from oxidant in the precursor; and
plasma treating the thin-film metal oxide layer with an open-air plasma to provide a plasma-treated thin-film metal oxide layer.

2. The method of claim 1, wherein the substrate is selected from the group consisting of: quartz, glass, UV and/or ozone treated glass, metals, metal oxides, polymers and polar surfaces.

3. The method of claim 1, wherein the depositing the precursor on the substrate comprises a deposition method selected from the group consisting of: ultrasonic spray deposition, blade coating, slot-die coating, spin coating, meniscus deposition, ink jet printing and gravure printing.

4. The method of claim 3, wherein the depositing the precursor on the substrate is performed from a nozzle that moves over the substrate at a speed of 1 mm/s or more.

5. The method of claim 1, wherein the metallic oxidant salt species includes one or more elements selected from the group consisting of: Li, Na, Mg, Al, K, Ti, Co, Ni, Cu, Zn, Ga, Zr, Cd, In, Sn, Ba, La, Hf and Ta.

6. The method of claim 1, wherein the metallic oxidant salt species includes one or more oxidants selected from the group consisting of: nitrates, chlorites, chlorates, perchlorates, hypochlorites, peroxydisulfates, peroxymonosulfates.

7. The method of claim 1, wherein the metallic non-oxidant salt species includes one or more elements selected from the group consisting of: Li, Mg, Al, Ti, Co, Ni, Cu, Zn, Ga, Zr, Cd, In, Sn, Ba, La, Hf and Ta.

8. The method of claim 1, where the metallic non-oxidant salt species includes one or more compounds selected from the group consisting of: metal acetylacetonate salts, metal chlorides, metal acetates, metal oxynitrates, metal fluorides, metal sulfates, metallic organo-ligated complexes, metal oxalates, and metal alkoxides.

9. The method of claim 1, wherein the non-metallic oxidant salt species includes one or more compounds selected from the group consisting of: ammonium nitrate, organic amine nitrate salts, quaternary ammonium nitrates, tetramethyl ammonium nitrate, chlorites, chlorates, perchlorates, hypochlorites, peroxydisulfates, and peroxymonosulfates.

10. The method of claim 1, wherein the non-metallic oxidant species includes one or more non-salt species selected from the group consisting of: nitric acid, peroxydisulfuric acids, peroxymonosulfuric acids, peracids, aliphatic or aromatic organic nitro compounds, nitrobenzene, nitropropane, nitroethane, nitrous oxides, peroxide-containing organic species, peroxides, and hydroperoxides.

11. The method of claim 1, wherein the at least one organic complexing fuel species acts as a metal complexing ligand to reduce metal hydroxide and/or oxide premature condensation and promote solubility of metallic species in organic solvents.

12. The method of claim 1, wherein the at least one organic complexing fuel species comprises one or more complexing compounds selected from the group consisting of: alcohols, ketones, aldehydes, carboxylic acids, esters, ethers, oximes, hydroxamic acids, diols, polyols, polyfunctional ethers, dimethoxyethane, polyethylene glycols, alpha and beta hydroxy aldehydes, beta diketones, beta keto esters, beta keto acids, and oxylates.

13. The method of claim 1, wherein the at least one organic complexing fuel species also includes one or more oxidizing species selected from the group consisting of: aromatic organic nitro compounds, aliphatic organic nitro compounds, nitroacetylacetone, nitro carboxylic acids, organic peroxides, organic hydroperoxides, and organic peracids.

14. The method of claim 13, wherein oxygen for the thin-film metal oxide comes in part from the one or more oxidizing species.

15. The method of claim 1, wherein the open-air plasma can provide a chemical environment selected from the group consisting of: reducing environments, oxidizing environments, and inert environments.

16. The method of claim 1, wherein the open-air plasma is selected from the group consisting of: blown arc discharges, capacitor discharges, microwave discharge, RF discharges, and flame plasmas.

17. The method of claim 1, wherein the open-air plasma includes one or more ionization gases selected from the group consisting of: air, oxygen, hydrogen in nitrogen, hydrogen in argon, hydrogen in helium, hydrogen in xenon, hydrogen in krypton, helium, argon, nitrogen, krypton, and xenon.

18. The method of claim 1, wherein the open-air plasma includes a gas shroud surrounding an afterglow of the open-air plasma.

19. The method of claim 18, wherein the gas shroud includes one or more gases selected from the group consisting of: air, oxygen, hydrogen in nitrogen, hydrogen in argon, hydrogen in helium, hydrogen in xenon, hydrogen in krypton, helium, argon, nitrogen, krypton, and xenon.

20. The method of claim 1, wherein oxidation to form the thin-film oxide is completed prior to the plasma treating.

21. The method of claim 1, wherein oxidation to form the thin-film oxide is completed during the plasma treating.

22. The method of claim 1, wherein the plasma treatment performs one or more treatments selected from the group consisting of: introducing oxygen vacancies, removing oxygen vacancies, exposure to ultraviolet light, elimination of dangling bonds, surface passivation, altering surface wetting properties, introducing surface defects, introducing bulk defects, densifying the thin-film metal oxide layer, performing precursor photolysis, and inducing crystallization.
